(19) United States
(12) Patent Application Publication
(10) Pub. No.: US 2026/0176129 A1
(43) Pub. Date: Jun. 25, 2026

(54) MICRO ELECTRO MECHANICAL SYSTEM DEVICE

(71) Applicants: BEIJING BOE TECHNOLOGY DEVELOPMENT CO., LTD., Beijing (CN); BOE TECHNOLOGY GROUP CO., LTD., Beijing (CN)

(72) Inventors: Wenbo LI, Beijing (CN); Jindou LIU, Beijing (CN); Zhihong DU, Beijing (CN); Hanbing ZHANG, Beijing (CN); Xiangyang ZHU, Beijing (CN); Xintong ZHU, Beijing (CN)

(73) Assignees: BEIJING BOE TECHNOLOGY DEVELOPMENT CO., LTD., Beijing (CN); BOE TECHNOLOGY GROUP CO., LTD., Beijing (CN)

(21) Appl. No.: 18/836,449

(22) PCT Filed: Mar. 31, 2023
(86) PCT No.: PCT/CN2023/085693

§ 371 Date: Aug. 7, 2024

(51) Int. Cl. B81B 7/00

(52) U.S. Cl. CPC B81B 7/0061; B81B 2201/036; B81B 2201/054; B81B 2203/0338; B81B 2203/04; B81B 2207/053

(57) ABSTRACT

A micro electro mechanical system device includes a pump portion, a valve portion, an air inlet, an air outlet, an interval channel and an accommodating region. The device further includes a first substrate, a first electrode layer, a second electrode layer, and a second substrate, after the first electrode layer and the second electrode layer being configured to generate a voltage difference, a distance being reduced to provide a first gas channel to circulate the gas, or to block the first gas channel; the pump portion and the valve portion sharing the first substrate and the second substrate, the first electrode layer including the first electrode of the pump portion and the third electrode of the valve portion, the second electrode layer including the second electrode of the pump portion and the fourth electrode of the valve portion.

### TECHNICAL FIELD

Embodiments of the present disclosure relate to a micro electro mechanical system device.

### BACKGROUND

Currently, Micro Electro Mechanical System (MEMS) devices are widely used in several different fields such as inkjet printers, MEMS gyroscopes, pressure sensors, lab-on-a-chip (LOC) applications, biosensors, and chemical sensors because of their small volume, ease of integration, and the like.

### SUMMARY

Embodiments of the present disclosure provide a micro electro mechanical system device. The micro electro mechanical system device includes a pump portion, a valve portion, an air inlet, and an air outlet, an interval channel being provided between the pump portion and the valve portion, a gas being configured to sequentially pass through the air inlet, the pump portion, the interval channel, the valve portion, and the air outlet. At least one of a side of the valve portion away from the air outlet and an inside of the valve portion is provided with an accommodating region, the gas is configured to be discharged from the air outlet after passing through the accommodating region; the micro electro mechanical system device includes a first substrate, a first electrode layer, a second electrode layer, and a second substrate which are sequentially stacked, an interval is arranged between the first electrode layer and the second electrode layer, after the first electrode layer and the second electrode layer are configured to generate a voltage difference, a distance between the second electrode layer and the first electrode layer is reduced to provide a first gas channel configured to circulate the gas, or to block the first gas channel; the pump portion and the valve portion share the first substrate and the second substrate, the pump portion includes a first electrode and a second electrode which are oppositely disposed, the valve portion includes a third electrode and a fourth electrode which are oppositely disposed, the first electrode layer includes the first electrode and the third electrode, the second electrode layer includes the second electrode and the fourth electrode, the first electrode and the third electrode are insulated from each other, and/or, the second electrode and the fourth electrode are insulated from each other.

For example, according to an embodiment of the present disclosure, the first electrode layer and the second electrode layer are configured such that after a voltage difference is generated, the second electrode layer bends toward the first electrode layer to provide the first gas channel between the second electrode layer and the second substrate.

For example, according to an embodiment of the present disclosure, the micro electro mechanical system device further includes: a third substrate located at a side of the second substrate away from the first substrate. The pump portion and the valve portion share the third substrate, and an interval is provided between the second substrate and the third substrate as a second gas channel for circulating the gas, the second gas channel includes the interval channel; the second substrate is provided with a first channel and a second channel penetrating through the second substrate in a direction perpendicular to the second substrate, the pump portion includes the first channel, the valve portion includes the second channel, the air inlet is communicated with the first channel of the pump portion, the first gas channel and the second gas channel, and the air outlet is communicated with the second channel of the valve portion, the first gas channel and the second gas channel.

For example, according to an embodiment of the present disclosure, the accommodating region includes a first groove disposed on a side of the third substrate facing the second substrate, the first groove is configured to place a scent material.

For example, according to an embodiment of the present disclosure, the micro electro mechanical system device further includes: a barrier located between the second electrode layer and the second substrate and configured to block the first gas channel when a voltage difference is not generated between the first electrode layer and the second electrode layer. In the direction perpendicular to the second substrate, the barrier has no overlap with both the first channel and the second channel.

For example, according to an embodiment of the present disclosure, at least one of the pump portion and the valve portion is provided with the barrier.

For example, according to an embodiment of the present disclosure, the micro electro mechanical system device further includes: a third electrode layer between the second electrode layer and the second substrate. The third electrode layer is provided with a space from the second electrode layer, and the third electrode layer is configured such that upon generating a voltage difference with the second electrode layer, the second electrode layer bends toward the third electrode layer to block the first gas channel.

For example, according to an embodiment of the present disclosure, at least one of the pump portion and the valve portion is provided with the third electrode layer.

For example, according to an embodiment of the present disclosure, the third substrate is provided with the air inlet and the air outlet penetrating the third substrate in a direction perpendicular to the third substrate, the air inlet communicates with the first gas channel through the first channel, and the air outlet communicates with the first gas channel through the second channel.

For example, according to an embodiment of the present disclosure, a plurality of spacing parts is disposed between the second substrate and the third substrate, the second gas channel is formed between adjacent spacing parts, and the spacing parts do not overlap with both the first channel and the second channel in the direction perpendicular to the second substrate.

For example, according to an embodiment of the present disclosure, the spacer part includes an adhesive layer to bond the second substrate and the third substrate.

For example, according to an embodiment of the present disclosure, the micro electro mechanical system device further includes: a functional layer between the first substrate and the second substrate; a first adhesive layer between the functional layer and the first substrate to bond the functional layer and the first substrate; a second adhesive layer between the functional layer and the second substrate to bond the functional layer and the second substrate. The second electrode layer is disposed on the functional layer.

For example, according to an embodiment of the present disclosure, a side of the first substrate facing the second substrate is provided with a plurality of second grooves, at least portions of the first electrode layer are located in the plurality of second grooves, the pump portion includes at least three second grooves arranged in a first direction to form at least three pump chambers, the valve portion includes at least one second groove to form at least one valve chamber, and an orthographic projection of the second electrode layer on the first substrate is completely located in the plurality of second grooves.

For example, according to an embodiment of the present disclosure, the first electrode layer and the second electrode layer corresponding to adjacent pump chambers are configured such that at least in part of time periods for applying electricity are staggered.

For example, according to an embodiment of the present disclosure, a side of the first electrode layer facing the second substrate is provided with a plurality of first spacers, a chamber is formed between adjacent first spacers, the pump portion includes at least three chambers, the valve portion includes at least one chamber, and an orthographic projection of the second electrode layer on the first substrate is completely located in an orthographic projection of the chamber on the first substrate.

For example, according to an embodiment of the present disclosure, after the first electrode layer and the second electrode layer are configured to generate a voltage difference, the first electrode layer bends toward the second electrode layer to block the first gas channel between the first electrode layer and the second electrode layer.

For example, according to an embodiment of the present disclosure, the second electrode layer is disposed on the second substrate, the second electrode layer is disposed between the second substrate and the first electrode layer, a plurality of second spacers are disposed between the first electrode layer and the second substrate, a chamber is formed between adjacent second spacers, the pump portion includes at least three chambers, the valve portion includes at least one chamber, and the second electrode layer is located in the chamber.

For example, according to an embodiment of the present disclosure, the pump portion includes at least one pump portion, the valve portion includes at least one valve portion, and the at least one pump portion is in communication with the at least one valve portion.

For example, according to an embodiment of the present disclosure, a depth of the second groove is 3-15 microns, a dimension of the second groove in a second direction is 1-5 millimeters, a dimension of the second groove in the first direction is 1-5 millimeters, and the second direction is perpendicular to the first direction and parallel to the second substrate.

For example, according to an embodiment of the present disclosure, a distance between adjacent second grooves in the pump portion is 1-3 mm.

For example, according to an embodiment of the present disclosure, the first spacer has a thickness of 2-10 microns.

For example, according to an embodiment of the present disclosure, the second spacer has a thickness of 3-15 microns.

### BRIEF DESCRIPTION OF DRAWINGS

In order to clearly illustrate the technical solution of the embodiments of the present disclosure, the drawings of the embodiments will be briefly described in the following; it is obvious that the described drawings are only related to some embodiments of the present disclosure and thus are not limitative of the present disclosure.

FIG. 1 is a schematic diagram of a partial cross-sectional structure of a micro electro mechanical system device according to an example of an embodiment of the present disclosure.

FIG. 2 is a schematic diagram of a partial cross-sectional structure of a first electrode layer and a second electrode layer of a valve portion shown in FIG. 1 after a voltage difference is generated.

FIG. 3 is a schematic diagram of a partial cross-sectional structure of a micro electro mechanical system device according to another example of an embodiment of the present disclosure.

FIG. 4 is a schematic diagram of a partial cross-sectional structure of a micro electro mechanical system device according to another example of an embodiment of the present disclosure.

FIG. 5 is a schematic diagram of a partial cross-sectional structure of a first electrode layer and a second electrode layer of a valve portion shown in FIG. 4 after a voltage difference is generated.

FIG. 6 is a schematic diagram of a partial cross-sectional structure of a micro electro mechanical system device according to another example of an embodiment of the present disclosure.

FIG. 7 is a schematic diagram of a partial cross-sectional structure of a first electrode layer and a second electrode layer of a valve portion shown in FIG. 6 after a voltage difference is generated.

FIG. 8 is a schematic diagram of a partial cross-sectional structure of a third electrode layer and a second electrode layer of the valve portion shown in FIG. 6 after a voltage difference is generated.

FIG. 9 is a schematic diagram of a partial cross-sectional structure of the valve portion of FIG. 1 according to another example of an embodiment of the present disclosure.

FIG. 10 is a schematic diagram of a partial cross-sectional structure of a micro electro mechanical system device according to another example of an embodiment of the present disclosure.

FIG. 11 is a schematic diagram of a partial cross-sectional structure of a pump portion or a valve portion of a micro electro mechanical system device according to another example of an embodiment of the present disclosure.

FIG. 12 is a schematic diagram of a partial cross-sectional structure of a first electrode layer and a second electrode layer of a pump portion or a valve portion shown in FIG. 11 after a voltage difference is generated.

FIGS. 13 and 14 are schematic diagrams of partial planar structures of micro electro mechanical system devices provided according to different examples of an embodiment of the present disclosure.

### DETAILED DESCRIPTION

In order to make objects, technical details and advantages of the embodiments of the present disclosure apparent, the technical solutions of the embodiment will be described in a clearly and fully understandable way in connection with the drawings related to the embodiments of the present disclosure. It is obvious that the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and the claims of the present application for disclosure, are not intended to indicate any sequence, amount or importance, but distinguish various components. The terms “comprise,” “comprising,” “include,” “including,” etc., are intended to specify that the elements or the objects stated before these terms encompass the elements or the objects and equivalents thereof listed after these terms, but do not preclude the other elements or objects.

The features “parallel”, “perpendicular” and “same” used in the embodiments of the present disclosure all include features such as “parallel”, “perpendicular” and “same” in the strict sense, and the cases having certain errors, such as “approximately parallel”, “approximately perpendicular”, “approximately the same” or the like, taking into account measurements and errors associated with the measurement of a particular quantity (e.g., limitations of the measurement system), and indicate being within an acceptable range of deviation for a particular value as determined by one of ordinary skill in the art. For example, “approximately” may indicate being within one or more standard deviations, or within 10% or 5% of the stated value. In the case that the quantity of a component is not specifically indicated below in the embodiments of the present disclosure, it means that the component may be one or more, or may be understood as at least one. “At least one” means one or more, and “plurality” means at least two. The “same layer” in the present disclosure refers to the structure formed by two (or more) structures formed by the same deposition process and patterned by the same patterning process, and their materials may be the same or different. The “integrated structure” in this disclosure refers to two (or more) structures which are formed by the same deposition process and patterned by the same patterning process, and their materials may be the same or different.

Embodiments of the present disclosure provide a micro electro mechanical system (MEMS) device including a pump portion, a valve portion, an air inlet, and an air outlet, an interval channel is provided between the pump portion and the valve portion, and a gas is configured to sequentially pass through the air inlet, the pump portion, the interval channel, the valve portion, and the air outlet. At least one of a side of the valve portion away from the air outlet and an inside of the valve portion is provided with an accommodating region, the gas is configured to be discharged from the air outlet after passing through the accommodating region. The micro electro mechanical system device includes a first substrate, a first electrode layer, a second electrode layer, and a second substrate which are sequentially stacked, an interval is arranged between the first electrode layer and the second electrode layer, after the first electrode layer and the second electrode layer are configured to generate a voltage difference, a distance between the second electrode layer and the first electrode layer is reduced to provide a first gas channel configured to circulate the gas, or to block the first gas channel; the pump portion and the valve portion share the first substrate and the second substrate, the pump portion includes a first electrode and a second electrode which are oppositely disposed, the valve portion includes a third electrode and a fourth electrode which are oppositely disposed, the first electrode layer includes the first electrode and the third electrode, the second electrode layer includes the second electrode and the fourth electrode, the first electrode and the third electrode are insulated from each other, and/or, the second electrode and the fourth electrode are insulated from each other.

The micro electro mechanical system device provided by the present disclosure achieves self-driving and on-off control of smell while reducing manufacturing cost through integrated and miniaturized design of the pump portion, the valve portion, and the accommodating region, enabling sharing of the pump portion and the valve portion to respective substrates to synchronously form the structure of the pump portion and the valve portion.

The micro electro mechanical system device provided by the embodiments of the present disclosure is described below in conjunction with the accompanying drawings.

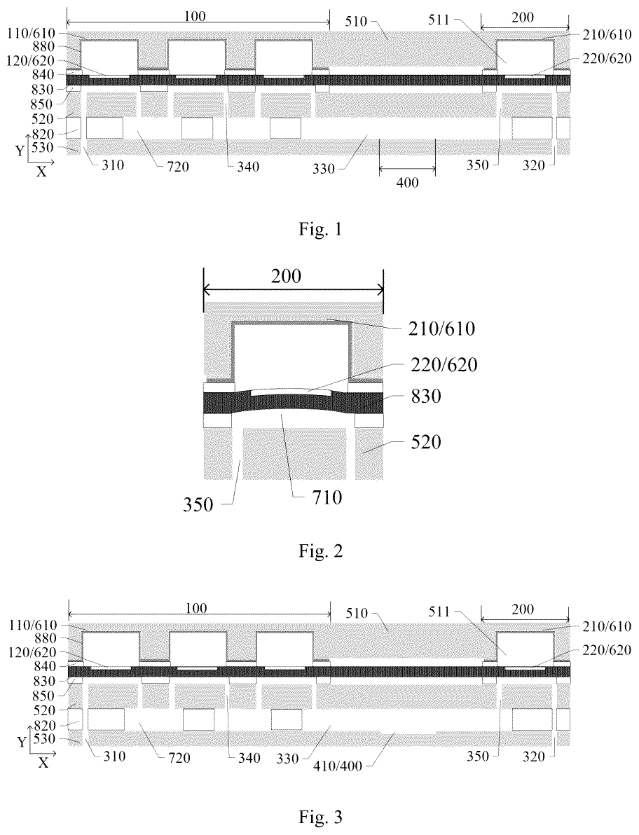

FIG. 1 is a schematic diagram of a partial cross-sectional structure of a micro electro mechanical system device according to an example of an embodiment of the present disclosure. FIG. 2 is a schematic diagram of a partial cross-sectional structure of the first electrode layer and the second electrode layer of the valve portion shown in FIG. 1 after a voltage difference is generated.

As shown in FIGS. 1 and 2, the micro electro mechanical system device includes a pump portion 100, a valve portion 200, an air inlet 310, and an air outlet 320. For example, the pump portion 100 and the valve portion 200 are spaced apart in the X-direction. The pump portion 100 is configured to circulate gas to provide aerodynamic force, and the valve portion 200 has a gas valve switching property configured to control the outflow of gas from the micro electro mechanical system device.

As shown in FIGS. 1 and 2, an interval channel 330 is provided between the pump portion 100 and the valve portion 200, and gas is configured to sequentially pass through the air inlet 310, the pump portion 200, the interval channel 330, the valve portion 200, and the air outlet 320. At least one of a side of the valve portion 200 away from the air outlet 320 and an inside of the valve portion 200 is provided with an accommodating region 400, the gas is configured to be discharged from the air outlet 320 after passing through the accommodating region 400.

FIG. 1 schematically shows that the accommodating region 400 is located in the interval channel 330 between the valve portion 200 and the pump portion 100. For example, the distance between the accommodating region 400 and the valve portion 200 may be greater than, less than, or equal to the distance between the accommodating region 400 and the pump portion 200, which is not limited by embodiments of the present disclosure and may be set according to device requirements. For example, the accommodating region 400 is configured to hold a scent material, such as an olfactory film, whereby the gas flowing out through the air outlet is a gas having a scent, such as a scent of flowers and fruits, a scent of plants and grass, or the like. For example, the scent material may be integrated in the micro electro mechanical system device. For example, the scent material may be placed as a replaceable material in the accommodating region after the micro electro mechanical system device is formed, such that after one scent material is exhausted, another scent material may be replaced in a certain manner.

As shown in FIGS. 1 and 2, the micro electro mechanical system device includes a first substrate 510, a first electrode layer 610, a second electrode layer 620, and a second substrate 520, which are sequentially stacked. For example, the first substrate 510, the first electrode layer 610, the second electrode layer 620, and the second substrate 520 may be stacked in the Y-direction.

As shown in FIGS. 1 and 2, an interval is arranged between the first electrode layer 610 and the second electrode layer 620, after the first electrode layer 610 and the second electrode layer 620 are configured to generate a voltage difference, a distance between the second electrode layer 620 and the first electrode layer 610 is reduced to provide a first gas channel 710 configured to circulate the gas, or the distance between the second electrode layer 620 and the first electrode layer 610 is increased to block the first gas channel 710.

In some examples, as shown in FIG. 2, the first electrode layer 610 and the second electrode layer 620 are configured such that upon generation of a voltage differential, the second electrode layer 620 bends toward the first electrode layer 610 to provide the first gas channel 710 between the second electrode layer 620 and the second substrate 520. FIG. 2 schematically shows that after a voltage difference is generated between the first electrode layer 610 and the second electrode layer 620, the distance between the second electrode layer 620 and the first electrode layer 610 decreases to provide the first gas channel 710 configured to pass gas. FIG. 2 schematically shows a cross-sectional view in which the distance between the third electrode 210 and the fourth electrode 220 (described later) in the valve portion 200 decreases after a voltage difference is generated, and a case that the first electrode 110 and the second electrode 120 in the pump portion 100 decreases after a voltage difference is generated can refer to FIG. 2. For example, in the pump portion, the first electrode and the second electrode are configured such that, after a voltage difference is generated, the second electrode is bent toward the first electrode to provide a first gas channel between the second electrode and the second substrate, or a distance between the second electrode and the first electrode is increased so as to block the first gas channel; in the valve portion, the third electrode and the fourth electrode are configured such that, upon generation of a voltage difference, the fourth electrode is bent toward the third electrode to provide a first gas channel between the fourth electrode and the second substrate, or a distance between the fourth electrode and the third electrode is increased so as to block the first gas channel.

For example, as shown in FIGS. 1 and 2, when different voltages are applied to the first electrode layer 610 and the second electrode layer 620, a voltage difference is generated between the two electrode layers, thereby generating an electrostatic driving force such that at least one of the first electrode layer 610 and the second electrode layer 620 is deformed by electrostatic action to reduce the spacing between the first electrode layer 610 and the second electrode layer 620. For example, the second electrode layer 620 is bent toward the first electrode layer 610 by electrostatic action to increase the distance between the second electrode layer 620 and the second substrate 520, thereby providing the first gas channel 710 required for gas flow.

For example, as illustrated in FIGS. 1 and 2, the degree of deformation of the second electrode layer 620 may be adjusted by adjusting the magnitude of the voltage difference between the first electrode layer 610 and the second electrode layer 620 to adjust the size of the first gas channel 710. For example, the first electrode layer 610 and the second electrode layer 620 may each be applied with a voltage other than 0 V, or one of the first electrode layer 610 and the second electrode layer 620 is applied with a voltage of 0 V and the other is applied with a bias voltage, or one of the first electrode layer 610 and the second electrode layer 620 is grounded and the other is applied with a bias voltage.

As shown in FIGS. 1 and 2, the pump portion 100 and the valve portion 200 share the first substrate 510 and the second substrate 520. For example, a portion of the first substrate 510 is a structure in the pump portion 100, a portion of the first substrate 510 is a structure in the valve portion 200; a portion of the second substrate 520 is a structure in the pump portion 100, and a portion of the second substrate 520 is a structure in the valve portion 200.

As shown in FIGS. 1 and 2, the pump portion 100 includes the first electrode 110 and the second electrode 120 disposed oppositely, the valve portion 200 includes the third electrode 210 and the fourth electrode 220 disposed oppositely, the first electrode layer 610 includes the first electrode 110 and the third electrode 210, the second electrode layer 620 includes the second electrode 120 and the fourth electrode 220, the first electrode 110 is disposed insulated from the third electrode 210, and/or the second electrode 120 is disposed insulated from the fourth electrode 220. For example, the first electrode 110 in the pump portion 100 and the third electrode 210 in the valve portion 200 are electrodes provided in the same layer, and the second electrode 120 in the pump portion 100 and the fourth electrode 220 in the valve portion 200 are electrodes provided in the same layer.

For example, as shown in FIG. 1, the first electrode 110 and the third electrode 210 are provided insulated, and the second electrode 120 is provided insulated from the fourth electrode 220.

The micro electro mechanical system device of the present disclosure provides self-driving and on-off control of odor while reducing manufacturing cost by enabling simultaneous formation of at least partial structures of the pump portion and the valve portion through integrated and miniaturized design of the pump portion, the valve portion, and the accommodating region, such as the pump portion and the valve portion sharing the first substrate and the second substrate, the first electrode of the pump portion being disposed in the same layer as the third electrode of the valve portion, and the second electrode of the pump portion being disposed in the same layer as the fourth electrode of the valve portion.

In some examples, as shown in FIGS. 1 and 2, the micro electro mechanical system device further includes a third substrate 530 on a side of the second substrate 520 away from the first substrate 510. For example, the third substrate 530 is disposed stacked with the second substrate 520.

In some examples, as shown in FIGS. 1 and 2, the pump portion 100 and the valve portion 200 share the third substrate 530. For example, a portion of the third base plate 530 is a structure in the pump portion 100, and a portion of the third base plate 530 is a structure in the valve portion 200.

In some examples, as shown in FIGS. 1 and 2, the second substrate 520 and the third substrate 530 are provided with a space therebetween as a second gas channel 720 for circulating the gas, the second gas channel 720 includes an interval channel 330. The second substrate 520 is provided with a first channel 340 and a second channel 350 penetrating the second substrate 520 in a direction perpendicular to the second substrate 520 (e.g., the Y direction in FIG. 1). For example, the first channel 340 and the second channel 350 are configured to communicate the first gas channel 710 and the second gas channel 720.

For example, as shown in FIG. 1, the first substrate 510, the second substrate 520, and the third substrate 530 may be made of the same material, such as glass.

In some examples, as shown in FIGS. 1 and 2, the pump portion 100 includes the first channel 340 and the valve portion includes the second channel 350. For example, the number of the first channels 340 and the second channels 350 are each an even number. For example, the number of first channels 340 is at least 6 and the number of second channels 350 is at least 2.

In some examples, as shown in FIGS. 1 and 2, the third substrate 530 is provided with the air inlet 310 and the air outlet 320 penetrating the third substrate 530 in a direction perpendicular to the third substrate 530 (e.g., the Y-direction in FIG. 1), the air inlet 310 communicates with the first gas channel 710 through the first channel 340, and the air outlet 320 communicates with the first gas channel 710 through the second channel 350.

In some examples, as shown in FIGS. 1 and 2, the air inlet 310 is in communication with the first channel 340 of the pump portion 100, the first gas channel 710, and the second gas channel 720, and the air outlet 320 is in communication with the second channel 350 of the valve portion 200, the first gas channel 710, and the second gas channel 720.

In some examples, as shown in FIGS. 1 and 2, a plurality of spacing parts 820 are disposed between the second substrate 520 and the third substrate 530, the second gas channel 720 is formed between adjacent spacing parts 820, and the spacing parts 820 do not overlap with either the first channel 340 or the second channel 350 in a direction perpendicular to the second substrate 520 to prevent the spacing parts from obscuring either the first channel or the second channel.

For example, as illustrated in FIG. 1, the spacing part 820 overlaps with the second electrode layer 620 in a direction perpendicular to the second substrate 520. For example, in the direction perpendicular to the second substrate 520, the spacing part 820 overlaps with the first electrode layer 610 to facilitate spacing the second substrate from the third substrate while avoiding the first channel and the second channel.

In some examples, as shown in FIG. 1, the spacing part 820 includes an adhesive layer to bond the second substrate 520 and the third substrate 530. For example, the spacing part 820 may have a dimension in the Y direction of 20-1000 microns. For example, the spacing part 820 may have the dimension in the Y direction of 30-800 microns. For example, the spacing part 820 may have the dimension in the Y direction of 40-600 microns. For example, the spacing part 820 may have the dimension in the Y direction of 50-500 microns. For example, the spacing part 820 may have the dimension in the Y direction of 60-400 microns, for example, the spacing part 820 may have the dimension in the Y direction of 70-300 microns. For example, the spacing part 820 may have the dimension in the Y-direction of 80-200 microns. For example, the spacing part 820 may have the dimension in the Y direction of 90-100 microns.

For example, as shown in FIG. 1, the space between the second substrate 520 and the third substrate 530 is used to accommodate the scent material and the passage of the airflow through the scent material. For example, the scent material may be placed on a surface of the third substrate 530 facing the second substrate 520.

For example, as shown in FIG. 1, the spacing size between the second substrate 520 and the third substrate 530 may be 20-1000 microns; within this size range, such as setting the distance between the second substrate 520 and the third substrate 530 smaller, it is advantageous to reduce the volume, such as the thickness, of the micro electro mechanical system device; assuming that the distance between the second substrate 520 and the third substrate 530 is set larger, more scent material may be accommodated between the second substrate 520 and the third substrate 530.

For example, as shown in FIG. 1, the spacing size between the second substrate 520 and the third substrate 530 may be 30-500 microns. For example, the spacing size between the second substrate 520 and the third substrate 530 may be 40-800 microns. For example, the spacing size between the second substrate 520 and the third substrate 530 may be 50-100 microns. For example, the spacing size between the second substrate 520 and the third substrate 530 may be 60-200 microns. For example, the spacing size between the second substrate 520 and the third substrate 530 may be 70-300 microns. For example, the spacing size between the second substrate 520 and the third substrate 530 may be 80-700 microns.

For example, as shown in FIGS. 1 and 2, taking the example that the pump portion 100 includes six first channels 340 and three first gas channels 710, and the valve portion 200 includes two second channels 350 and one first gas channel 710 as an example, when both the pump portion 100 and the valve portion 200 are in an open state, such as when the second electrode 120 in the pump portion 100 is bent toward the first electrode 110 to provide the first gas channels 710 in the pump portion 100, and the fourth electrode 220 in the valve portion 200 is bent toward the third electrode 210 to provide the first gas channels 710 in the valve portion 200, the gas entering the micro electro mechanical system device from the air inlet 310 sequentially passes through the second gas channel 720, the first channel 340, the first gas channel 710, the first channel 340, the second gas channel 720, the first channel 340, the first gas channel 710, the first channel 340, the second gas channel 720, the first channel 340, the first gas channel 710, the first channel 340, the second gas channel 720, the second channel 350, the first gas channel 710, the second channel 350, and the second gas channel 720, and then exits the micro electro mechanical system device from the air outlet 320.

In some examples, as shown in FIGS. 1 and 2, the micro electro mechanical system device further includes a functional layer 830 located between the first substrate 510 and the second substrate 520, a first adhesive layer 840 located between the functional layer 830 and the first substrate 510 to bond the functional layer 830 and the first substrate 510, and a second adhesive layer 850 located between the functional layer 830 and the second substrate 520 to bond the functional layer 830 and the second substrate 520, and the second electrode layer 620 is disposed on the functional layer 830, such as the second electrode layer 620 may be disposed on a surface of the functional layer 830 facing the first electrode layer 610 or a surface of the functional layer 830 away from the first electrode layer 610.

The micro electro mechanical system device provided by the present disclosure provides a flow-through channel of gas in the micro electro mechanical system and a switching channel of the pump portion and the valve portion through the arrangement of the positional relationship of the first substrate, the second substrate, the third substrate, the first electrode layer, the second electrode layer, the functional layer, and the spacer part, and realizes a miniaturized integrated design of the pump portion, the valve portion, and the accommodating region.

For example, as shown in FIG. 1, an orthographic projection of the second electrode layer 620 on the first substrate 510 does not overlap with orthographic projections of the first adhesive layer 840 and the second adhesive layer 850 on the first substrate 510 to prevent the adhesive layers from affecting the bending effect of the second electrode layer.

For example, as shown in FIG. 1, the orthographic projection of the first adhesive layer 840 on the first substrate 510 overlaps with the orthographic projection of the second adhesive layer 850 on the first substrate 510 to facilitate supporting the functional layer such that the functional layer is in a flat state when no voltage difference is generated between the first electrode layer and the second electrode layer. For example, the first adhesive layer 840 may include a plurality of glue blocks and the second adhesive layer 850 may include a plurality of glue blocks.

For example, as shown in FIG. 1, in the direction perpendicular to the second substrate 520, the first adhesive layer 840 located between the adjacent grooves 511 (described later) does not overlap with the spacing part 820, and the first adhesive layer 840 located at the most edge overlaps with the spacing part 820 to prevent the spacer part from blocking the flow-through passage of the gas.

For example, as shown in FIGS. 1 and 2, the second electrode layer 620 may be embedded in the surface of the functional layer 830. For example, the functional layer 830 may have a flexible material such as polyimide (PI) or the like.

For example, as shown in FIGS. 1 and 2, when a voltage difference is generated between the first electrode layer 610 and the second electrode layer 620, the functional layer 830 bends toward the first electrode layer 610 along with the second electrode layer 620 when the second electrode layer 620 bends toward the first electrode layer 610 by electrostatic action. For example, functional layer 830 may also be referred to as a pump valve layer, e.g., the magnitude of bending of the pump valve layer with the second electrode layer toward the first electrode layer may be referred to as the magnitude of motion, which is related to the voltage difference and distance between the first electrode layer and the second electrode layer.

For example, as shown in FIG. 1, the thickness of the functional layer 830 is greater than the thickness of the second electrode layer 620. For example, the first adhesive layer 840 and the second adhesive layer 850 may have a thickness of 1-3 microns, and the functional layer 830 may have a thickness of 2-10 microns. For example, the functional layer 830 may have a thickness of 3 to 9 microns. For example, the functional layer 830 may have a thickness of 4-6 microns. For example, the functional layer 830 may have a thickness of 5-8 microns. For example, the thickness of the first adhesive layer 840 and the thickness of the second adhesive layer 850 may be the same.

For example, as shown in FIG. 1, the distance between the first substrate 510 and the second substrate 520 may be 3-13 microns; within this range, assuming that the distance between the first substrate 510 and the second substrate 520 is smaller, the volume of the micro electro mechanical system device is smaller, e.g., the thickness is smaller. As the distance between the first substrate 510 and the second substrate 520 is larger, the process of the first electrode layer and the second electrode layer is better realized, and the functional layer and the second electrode layer can increase the motion amplitude under the action of a larger electrostatic force generated by a larger voltage difference to facilitate the circulation of the gas in the micro electro mechanical system device.

In some examples, as shown in FIGS. 1 and 2, a side of the first substrate 510 facing the second substrate 520 is provided with a plurality of grooves 511 (also referred to as second grooves 511), at least portions of the first electrode layer 610 are located in the plurality of grooves 511, the pump portion 100 includes at least three grooves 511 arranged in the first direction to form at least three pump chambers, the valve portion 200 includes at least one groove 511 to form at least one valve chamber, and an orthographic projection of the second electrode layer 620 on the first substrate 510 is located completely located within the plurality of grooves 511. The pump portion is provided with at least three pump chambers to provide sufficient power for gas circulation.

For example, FIG. 1 schematically shows that the first direction is the X-direction. For example, the plurality of pump chambers included in the pump portion 100 and the valve chamber included in the valve portion 200 are arranged in the first direction.

FIG. 1 schematically shows that the number of pump chambers is three and the number of valve chambers is one, but is not limited thereto, and the number of pump chambers may also be four, five or more, and the number of valve chambers may also be two, three or more. For example, the number of valve chambers may be less than or equal to the number of pump chambers, and the number of pump chambers and valve chambers may be set according to device requirements.

In some examples, as shown in FIGS. 1 and 2, the depth of the groove 511 is 3-15 microns, the dimension of the groove 511 in the second direction is 1-5 millimeters, the dimension of the groove 511 in the first direction is 1-5 millimeters, and the second direction is perpendicular to the first direction and parallel to the second substrate 510. For example, the second direction may be a direction perpendicular to the XY plane.

For example, as shown in FIGS. 1 and 2, the groove 511 has a depth of 4-14.5 microns. For example, the groove 511 has a depth of 3.5-14 microns. For example, the groove 511 has a depth of 5-10 microns. For example, the groove 511 has a depth of 4.5-12 microns. For example, the groove 511 has a depth of 5.5-13.5 microns. For example, the groove 511 has a depth of 6-9 microns. For example, the groove 511 has a depth of 7-11 microns. For example, the dimensions of the groove 511 in the first direction and the second direction may be the same. For example, the grooves 511 may have dimensions of 2-4 microns in both the first direction and the second direction. For example, the grooves 511 may have dimensions of 2.5-3 microns in both the first direction and the second direction. For example, the grooves 511 may have dimensions of 3.5-4.5 microns in both the first direction and the second direction.

For example, as shown in FIGS. 1 and 2, the pump chamber and the valve chamber may have the same dimensional characteristics.

In some examples, as shown in FIGS. 1 and 2, the distance between adjacent grooves 511 in the pump portion 100 is 1-3 millimeters. For example, the distance between adjacent grooves 511 in the pump portion 100 may be 1.5-2 microns. For example, the distance between adjacent grooves 511 in the pump portion 100 may be 1.8-2.5 mm. For example, the distance between adjacent grooves 511 in the pump portion 100 may be smaller than the dimension of the grooves 511 in the first direction. For example, the minimum distance between the groove 511 of the pump portion 100 and the groove 511 of the valve portion 200 is greater than the distance between adjacent grooves 511 in the pump portion 100.

For example, as shown in FIG. 1, one pump chamber corresponds to two first channels 340 and one valve chamber corresponds to two second channels 350. For example, one line extending in the Y-direction may pass through the first channel 340 and the pump chamber, and another line extending in the Y-direction may pass through the second channel 350 and the valve chamber.

For example, as shown in FIG. 1, the first electrode layer 610 includes portions located in the grooves 511 and between adjacent grooves 511, e.g., the first electrode layer 610 is conformally formed on a surface of the first substrate 510 facing the second substrate 520. For example, a surface of the first electrode layer 610 away from the first substrate 510 may be provided with the insulating layer 880, e.g., the insulating layer 880 is conformally formed on a surface of the first electrode layer 610 away from the first substrate 510. For example, the material of the insulating layer 880 may include silicon oxide, silicon nitride, or the like.

For example, as shown in FIG. 1, the first electrode layers 610 arranged in the plurality of pump chambers included in the pump portion 100 may be electrically connected electrode layers, and the second electrode layers 620 arranged in the plurality of pump chambers may be separated from one another, advantageously enabling time-sharing control of the different pump chambers, enabling the function of a peristaltic pump.

In some examples, as shown in FIG. 1, the first electrode layer 610 and the second electrode layer 620 corresponding to adjacent pump chambers in the pump portion are configured such that at least in part of time periods for applying electricity are staggered. For example, the plurality of pump chambers included in the pump portion 100 are driven sequentially to achieve the function of a peristaltic pump.

For example, as shown in FIG. 1, taking the pump portion 100 including three pump chambers P1, P2, and P3 arranged sequentially in the X-direction as an example, the pump chamber P1 is the pump chamber closest to the air inlet 310; the different timing drives may include three time periods, such as T1, T2, and T3.

For example, in one example, only one pump chamber is power-driven in one time period, such as in T1 phase, pump chamber P1 is power-driven, and pump chambers P2 and P3 are not power-driven; in T2 stage, the pump chamber P2 is power-driven, and the pump chambers P1 and P3 are not power-driven; in T3 stage, pump chamber P3 is power-driven and pump chambers P1 and P2 are not power-driven.

For example, in another example, two pump chambers are power-driven in one time period, such as in T1 phase, pump chambers P1 and P2 are power-driven, and pump chamber P3 is not power-driven; in T2 stage, the pump chambers P2 and P3 are power-driven, and the pump chamber P1 is not power-driven; in T3 stage, the pump chambers P1 and P3 are power-driven, and the pump chamber P2 is not power-driven.

For example, as shown in FIG. 1, the pump portion 100 includes three pump chambers P1, P2, and P3 arranged sequentially in the X-direction, the pump chamber P1 is the pump chamber closest to the air inlet 310; the different timing drives include six time periods, such as T1, T2, T3, T4, T5, and T6.

For example, in one example, different chambers may be power-driven in turns during different time periods, e.g., in T1 phase, pump chamber P1 is power-driven, and pump chambers P2 and P3 are not power-driven; in T2 stage, the pump chambers P1 and P2 are power-driven, and the pump chamber P3 is not power-driven; in T3 stage, the pump chambers P1, P2 and P3 are all power-driven; in T4 stage, the pump chambers P2 and P3 are power-driven, and the pump chamber P1 is not power-driven; T5 stage, the pump chamber P3 is power-driven, and the pump chambers P1 and P2 are not power-driven; in T6 phase, none of the pump chambers P1, P2 and P3 are power-driven.

For example, as shown in FIG. 1, the voltage difference applied to the first electrode layer 610 and the second electrode layer 620 in the pump portion 100 may be the same as or different from the voltage difference applied to the first electrode layer 610 and the second electrode layer 620 in the valve portion 200, and the voltage may be applied according to the requirements of the micro electro mechanical system device.

For example, as shown in FIG. 1, the valve chambers in the valve portion 200 may coincide with the opening times of the pump chambers in the pump portion 100 that are closest to the valve portion 200, the valve chambers in the valve portion 200 may be opened during the different time periods described above, or the valve chambers in the valve portion 200 may be opened after the pump chambers are closed. The opening time of the valve portion may be set according to device requirements.

For example, in fabricating the micro electro mechanical system device of FIG. 1, the fabrication method includes forming a mask on a first substrate material and etching the first substrate material to form a first substrate 510 with grooves 511, the mask as mentioned above may include positive photoresist, the first substrate material may include silicon or glass, the silicon substrate material may adopt deep reactive ion etching (DRIE), and the glass substrate material may adopt hydrogen fluoride (HF) vapor phase etching.

For example, in fabricating the micro electro mechanical system device shown in FIG. 1, the fabrication method further includes sputtering the first electrode layer 610 on the side of the first substrate 510 having the groove 511. For example, the material of the first electrode layer 610 includes aluminum (Al) and molybdenum (Mo). The thickness of molybdenum may be 20 nm and the thickness of aluminum may be 200 nm.

For example, in fabricating the micro electro mechanical system device shown in FIG. 1, the fabrication method may further include forming an insulating layer 880 on the first electrode layer 610, such as growing a silicon nitride layer on the first electrode layer 610. For example, the insulating layer 880 may have a thickness of 200 nm.

For example, in fabricating the micro electro mechanical system device of FIG. 1, the fabrication method further includes coating a sacrificial layer (DBL) on a transfer substrate, and then patterning to form the second electrode layer 620 on the sacrificial layer. For example, the material of the second electrode layer 620 may include aluminum (Al) and molybdenum (Mo), such as aluminum may have a thickness of 200 nanometers and molybdenum may have a thickness of 20 nanometers. For example, after forming the second electrode layer 620, the functional layer 830 is coated on the second electrode layer 620 and cured. For example, the material of the functional layer 830 may be polyimide (PI). For example, the materials of the first electrode layer and the second electrode layer may be the same. For example, the thickness of the first electrode layer and the thickness of the second electrode layer may be the same.

For example, in fabricating the micro electro mechanical system device shown in FIG. 1, the fabrication method further includes bonding the side of the transfer substrate provided with the second electrode layer 620 to the side of the first substrate 510 provided with the first electrode layer 610, such as by bonding the two through the first adhesive layer 840; the transfer substrate is then peeled off.

For example, in fabricating the micro electro mechanical system device of FIG. 1, the fabrication method further includes laser drilling the second substrate material to form the second substrate 520 having the first channel 340 and the second channel 350, and then bonding the second substrate 520 with the functional layer 830.

For example, each adhesive layer in embodiments of the present disclosure may include one or several of optically clear adhesive (OCA), photosensitive adhesive (UV adhesive), polymethyl methacrylate (PMMA) double-sided adhesive, and the like.

FIG. 3 is a schematic diagram of a partial cross-sectional structure of a micro electro mechanical system device according to another example of an embodiment of the present disclosure. The micro electro mechanical system device of FIG. 3 differs from the micro electro mechanical system device of FIG. 1 in that the accommodating region 400 includes a groove 410 (also referred to as a first groove 410) disposed on a side of the third substrate 530 facing the second substrate 520, the groove 410 is configured to place a scent material, such as an olfactory film (not shown). The first substrate, the second substrate, the first electrode layer, the second electrode layer, the functional layer, the first adhesive layer, the second adhesive layer, and the spacing part in the micro electro mechanical system device of FIG. 3 may have the same features as those of the micro electro mechanical system device of FIG. 1, and will not be described in detail herein.

By providing a groove for placing the scent material on the side of the third substrate facing the second substrate, the placement and preservation of the scent material is facilitated.

For example, as shown in FIG. 3, the depth of the groove 410 may be 100-400 microns, and the length and width of the groove 410 may be 500-2500 microns. The length and width of the groove 410 may refer to the dimension of the groove 410 along the X direction as well as the dimension in the direction perpendicular to the XY plane. The length and width of the groove cannot be set too long to prevent increasing the flow distance of the gas to increase the loss of the gas; the length and width of the groove also cannot be set too short to affect the placement of the scent material.

For example, as shown in FIG. 3, the depth of the groove 410 may be 150-350 microns. For example, the depth of the groove 410 may be 180-250 microns. For example, the depth of the groove 410 may be 200-380 microns. For example, the length and width of the groove 410 may be the same or different. For example, the length and width of the groove 410 may be 600-2400 microns. For example, the length and width of the groove 410 may be 700-2000 microns. For example, the length and width of the groove 410 may be 800-2200 microns. For example, the length and width of the groove 410 may be 1000-1500 microns. For example, the length and width of the groove 410 may be 900-1200 microns. For example, the length and width of the groove 410 may be 1100-1800 microns. For example, the preparation process of the groove 410 may be the same as the preparation process of the groove 511, and will not be repeated here.

For example, as shown in FIGS. 1-3, the scent material may include a fragrance film, which may include a variety of different material systems, such as in an acrylamide system, where acrylamide, cross-linking agent, initiator, accelerator may be mixed in a certain proportion, and then a certain volume of a solution (e.g., 3 ml, mass 3.03 g) may be measured into a groove 410 using a pipette, and a scent of a particular scent (e.g., 600 μl, mass 0.502 g) may be measured into the groove 410 using the pipette, and then it is placed at room temperature for one day to complete curing and film formation. For example, the mass proportion of acrylamide may be 15% and the amount may be 7.5 g. For example, the cross-linking agent may be present in a mass proportion of 0.5% and used in an amount of 0.25 g. For example, the initiator may be present in a mass proportion of 0.1% and used in an amount of 0.05 g. For example, the mass proportion of the accelerator may be 0.05% and the amount may be 25 μl. For example, the cross-linking agent may include polyethylene glycol, N,N′-methylenebisacrylamide, or the like. For example, the initiator may include ammonium persulfate, potassium persulfate, azobisisobutyronitrile, and the like. For example, the accelerator may include tetramethylethylenediamine or the like.

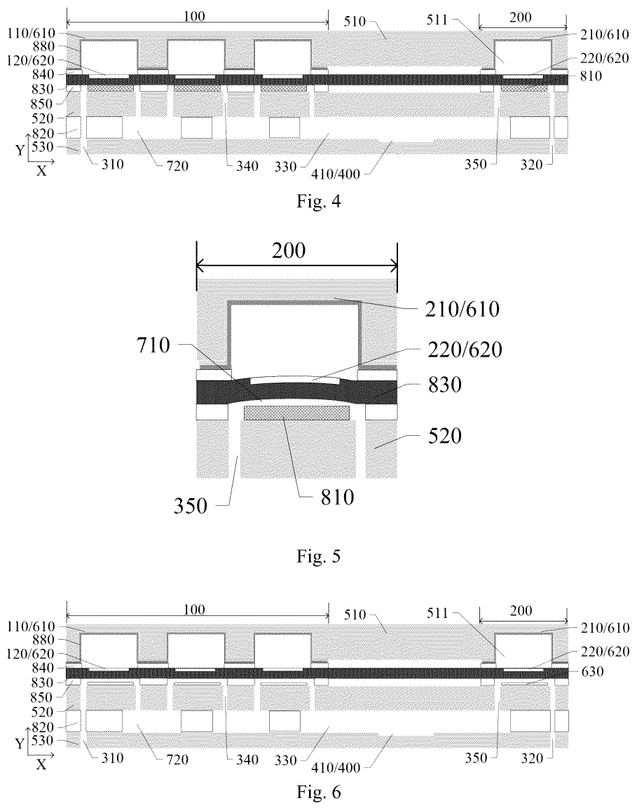

FIG. 4 is a schematic diagram of a partial cross-sectional structure of a micro electro mechanical system device according to another example of an embodiment of the present disclosure. FIG. 5 is a schematic diagram of a partial cross-sectional structure of a first electrode layer and a second electrode layer of a valve portion shown in FIG. 4 after a voltage difference is generated. The micro electro mechanical system device of FIG. 4 differs from the micro electro mechanical system device of FIG. 3 in that the micro electro mechanical system device further includes a barrier 810 located between the second electrode layer 620 and the second substrate 520, the barrier 810 is configured to block the first gas channel 710 when no voltage difference is generated between the first electrode layer 610 and the second electrode layer 620.

For example, as shown in FIGS. 4 and 5, the barrier 810 may be in contact with a surface of the second electrode layer 620 or the functional layer 830 to effect blocking of the first gas channel 710. For example, the barrier 810 may be a single-sided adhesive with the adhesive side adhering to the second substrate 520 and the other side contacting, but not adhering to, the second electrode layer 620 or the functional layer 830.

The first substrate, the second substrate, the first electrode layer, the second electrode layer, the functional layer, the first adhesive layer, the second adhesive layer, and the spacing part in the micro electro mechanical system device of FIG. 4 may have the same features as those of the micro electro mechanical system device of FIG. 1, and will not be repeated herein. The third substrate shown in FIG. 4 has the same feature as the third substrate shown in FIG. 3 and will not be described in detail herein.

By providing a barrier between the second electrode layer and the second substrate to fill the gap between the functional layer or the second electrode layer and the second substrate, it is advantageous to improve the switching performance of the micro electro mechanical system device and to alleviate the gas leakage phenomenon.

In some examples, as shown in FIGS. 4 and 5, in a direction perpendicular to the second substrate 520, the barrier 810 does not overlap with both the first channel 340 and the second channel 350 to prevent the barrier 810 from blocking circulate of gas through the channels in the second substrate.

In some examples, as shown in FIGS. 4 and 5, at least one of the pump portion 100 and the valve portion 200 is provided with the barrier 810. For example, both the pump portion 100 and the valve portion 200 are provided with the barrier 810 to improve the gas blocking effect of the pump portion and the valve portion in the closed state.

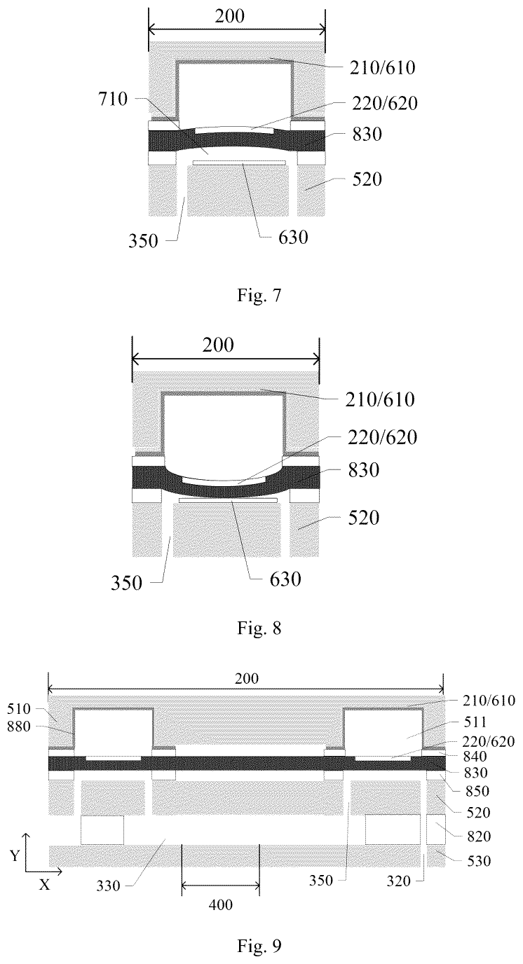

FIG. 6 is a schematic diagram of a partial cross-sectional structure of a micro electro mechanical system device according to another example of an embodiment of the present disclosure. FIG. 7 is a schematic diagram of a partial cross-sectional structure of a first electrode layer and a second electrode layer of a valve portion shown in FIG. 6 after a voltage difference is generated. FIG. 8 is a schematic diagram of a partial cross-sectional structure of a third electrode layer and a second electrode layer of the valve portion shown in FIG. 6 after a voltage difference is generated.

The micro electro mechanical system device of FIG. 6 differs from the micro electro mechanical system device of FIG. 3 in that the micro electro mechanical system device further includes a third electrode layer 630 located between the second electrode layer 620 and the second substrate 520, the third electrode layer 630 is spaced apart from the second electrode layer 620, the third electrode layer 630 is configured such that upon generating a voltage difference with the second electrode layer 620, the second electrode layer 620 bends toward the third electrode layer 630 to block the first gas channel 710. For example, the space between the third electrode layer 630 and the second electrode layer 620 to provide a space in which the second electrode layer 620 is bent toward the third electrode layer 630.

By providing the third electrode layer between the second electrode layer and the second substrate to block the gap between the functional layer or the second electrode layer and the second substrate, it is advantageous to improve the switching performance of the micro electro mechanical system device and to alleviate the gas leakage phenomenon.

For example, as illustrated in FIGS. 6 to 8, the third electrode layer 630 may employ the same material as the first electrode layer 610 or the second electrode layer 620.

For example, as shown in FIGS. 6 to 8, when different voltages are applied to the first electrode layer 610 and the second electrode layer 620, a voltage difference is generated between the two electrode layers, thereby generating an electrostatic driving force, so that the second electrode layer 620 bends toward the first electrode layer 610 by electrostatic action to increase a distance between the second electrode layer 620 and the second substrate 520, thereby providing the first gas channel 710 required for gas circulation. For example, when different voltages are applied to the second electrode layer 620 and the third electrode layer 630, a voltage difference is generated between the two electrode layers, thereby generating an electrostatic driving force so that the second electrode layer 620 bends toward the third electrode layer 610 by electrostatic action to block the first gas channel 710.

For example, as illustrated in FIGS. 6 to 8, the second electrode layer 620 as a common electrode may be grounded, and the first electrode layer 610 and the third electrode layer 630 as signal electrodes. For example, when the voltage of the second electrode layer 620 is set to 0, the voltages of the first electrode layer 610 and the third electrode layer 630 are set to 0, such as the first electrode layer 610, the second electrode layer 620 and the third electrode layer 630 are grounded, there is no voltage difference between the first electrode layer 610 and the second electrode layer 620, there is no voltage difference between the second electrode layer 620 and the third electrode layer 630, and the second electrode layer 620 is not bent by electrostatic force. For example, when the second electrode layer 620 is grounded, the first electrode layer 610 is applied with a bias voltage, and the voltage of the third electrode layer 630 is set to 0, e.g., grounded, the operation state of the second electrode layer 620 is bent toward the first electrode layer 610 as shown in FIG. 7 to increase the distance between the second electrode layer 620 and the second substrate 520, thereby providing the first gas channel 710 required for gas circulation. For example, when the second electrode layer 620 is grounded, the voltage of the first electrode layer 610 is set at 0, e.g., grounded, and the third electrode layer 630 is applied with a bias voltage, the operation state of the second electrode layer 620 is bent toward the third electrode layer 630 as shown in FIG. 8 to block the first gas channel 710.

For example, as shown in FIG. 8, when the second electrode layer 620 is bent toward the third electrode layer 630, the second electrode layer 620 or the functional layer 830 is in contact with the third electrode layer 630 to block the first gas channel 710.

In some examples, as shown in FIGS. 6-8, at least one of the pump portion 100 and the valve portion 200 is provided with the third electrode layer 630. FIGS. 7 and 8 schematically show cross-sectional views in which a distance between the third electrode 210 and the fourth electrode 220 is reduced and a distance between the fourth electrode 220 and the third electrode layer 630 is reduced after voltage differences are generated in the third electrode 210, the fourth electrode 220, and the third electrode layer 630 in the valve portion 200, and a case in which the distance is reduced after a voltage difference is generated in the first electrode 110 and the second electrode 120 in the pump portion 100 and a case in which the distance is reduced after a voltage difference is generated in the second electrode 120 and the third electrode layer 630.

For example, as shown in FIGS. 6 to 8, the pump portion 100 and the valve portion 200 are each provided with the third electrode layer 630 to improve the gas blocking effect of the pump portion and the valve portion in the closed state.

FIG. 9 is a schematic diagram of a partial cross-sectional structure of the valve portion of FIG. 1 according to another example of an embodiment of the present disclosure. The valve portion shown in FIG. 9 differs from the valve portion shown in FIG. 1 in that the valve portion 200 shown in FIG. 9 includes two valve chambers. Other structures in the micro electro mechanical system device shown in FIG. 9 may have the same features as those in any of the examples shown in FIGS. 1-8, and will not be described in detail herein. For example, the valve portion 200 shown in FIG. 9 may include the barrier 810 shown in FIG. 4 or the third electrode layer 630 shown in FIG. 6.

For example, as shown in FIG. 9, the accommodating region 400 may be located at the valve portion 200. For example, the accommodating region 400 may employ the groove 410 as shown in FIG. 4. For example, the accommodating region 400 may be located between two valve chambers.

For example, as shown in FIG. 9, the two valve chambers included in the valve portion 200 may be in the open state at the same time or in the open state in different periods.

For example, FIG. 9 schematically shows that the third electrodes 210 corresponding to the two valve chambers are arranged at intervals, but is not limited thereto, and the third electrodes corresponding to the two valve chambers may be integrally arranged.

The two valve chambers shown in FIG. 9 may have the same features as the valve chambers in the valve portion shown in FIGS. 1 to 8 and will not be repeated here. The present example schematically shows that the valve portion includes two valve chambers, but is not limited thereto, and may also include three or more valve chambers.

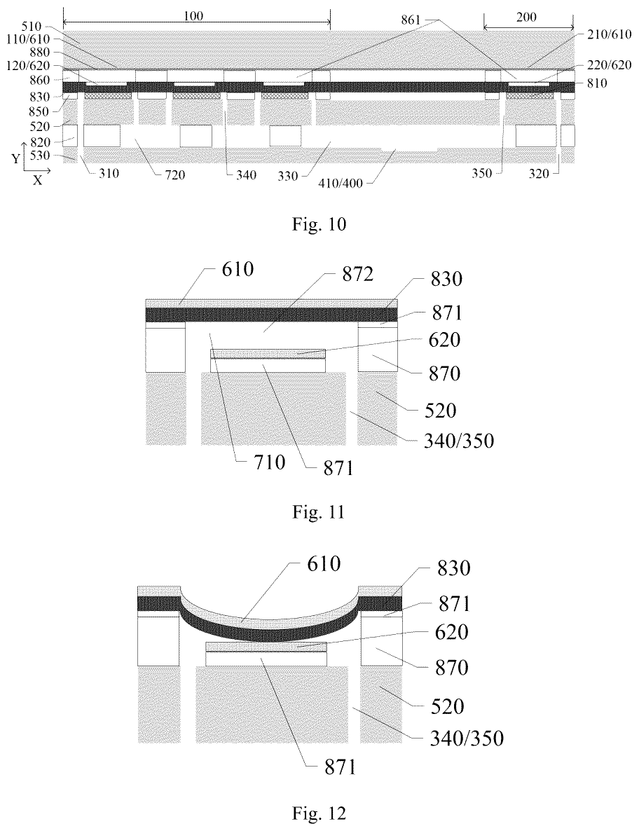

FIG. 10 is a schematic diagram of a partial cross-sectional structure of a micro electro mechanical system device according to another example of an embodiment of the present disclosure. The micro electro mechanical system device shown in FIG. 10 differs from the micro electro mechanical system device shown in FIG. 4 in the shape of the first substrate 510. The second electrode layer, the functional layer, the second substrate, the spacing part, and the third substrate in the micro electro mechanical system device shown in FIG. 10 have the same features as in the micro electro mechanical system device of any of the above examples, and are not repeated here. The barrier 810 shown in FIG. 10 may be replaced with the third electrode layer 630 shown in FIG. 6, the third substrate 530 shown in FIG. 10 may not be provided with the groove 410, and the number of the pump chambers and the valve chambers shown in FIG. 10 is only schematic, and the number of the pump chambers shown in FIG. 10 may be four or more, and the number of the valve chambers may be two or more.

In some examples, as shown in FIG. 10, a side of the first electrode layer 610 facing the second substrate 520 is provided with a plurality of first spacers 860, a chamber 861 is formed between adjacent first spacers 860, the pump portion 100 includes at least three chambers 861, the valve portion 200 includes at least one chamber 861, and an orthographic projection of the second electrode layer 620 on the first substrate 510 is completely located in an orthographic projection of the chambers 861 on the first substrate 510.

For example, as shown in FIG. 10, the first spacer 860 includes an adhesive layer to bond the first substrate 510 and the functional layer 830.

For example, as shown in FIG. 10, the first electrode 110 of the pump portion 100 and the third electrode 210 of the valve portion 200 may be integrally formed or spaced apart. For example, the second electrode 120 of the pump portion 100 and the fourth electrode 220 of the valve portion 200 are insulated.

In some examples, as shown in FIG. 10, the first spacer 860 has a thickness of 2-10 microns. For example, the first spacer 860 may have the thickness of 3-5 microns. For example, the first spacer 860 may have the thickness of 4-7 microns. For example, the first spacer 860 may have the thickness of 4-7 microns. For example, the first spacer 860 may have the thickness of 6-9 microns.

FIG. 11 is a schematic diagram of a partial cross-sectional structure of a pump portion or a valve portion of a micro electro mechanical system device according to another example of an embodiment of the present disclosure. FIG. 12 is a schematic diagram of a partial cross-sectional structure of a first electrode layer and a second electrode layer of a pump portion or a valve portion shown in FIG. 11 after a voltage difference is generated.

The micro electro mechanical system device of FIG. 11 and FIG. 12 differs from the micro electro mechanical system device of any of the examples of FIG. 1 to FIG. 10 in that the first electrode layer 610 and the second electrode layer 620 are configured such that the distance between the first electrode layer 610 and the second electrode layer 620 decreases to block the first gas channel 710 between the first electrode layer 610 and the second electrode layer 620 after the voltage difference is generated. For example, the first electrode layer 610 is bent toward the second electrode layer 620 to block the first gas channel 710 between the first electrode layer 610 and the second electrode layer 620.

FIGS. 11 and 12 only schematically show the first electrode layer 610, the functional layer 830, the second electrode layer 620, and the second substrate 520, and do not show the first substrate and the third substrate. The first substrate in this example may have a groove as shown in FIG. 1 or may have no groove as shown in FIG. 10, and a certain interval is arranged between the first electrode layer and the first substrate to realize that the first electrode layer is bent by electrostatic action; the second electrode layer is fixed on the second substrate; the second substrate may have corresponding features as in the second substrate in the previous examples, and the third substrate may have corresponding features as in the third substrate in the previous examples, which are not repeated here.

When the first electrode layer 610 and the second electrode layer 620 of the pump portion and the valve portion shown in FIGS. 11 and 12 do not generate a voltage difference, the pump portion and the valve portion are in a normally open mode, and the first gas channel 710 can circulate gas; when a voltage difference is generated between the first electrode layer 610 and the second electrode layer 620 of the pump portion and the valve portion, an electrostatic driving force is generated, so that the first electrode layer 610 is deformed by an electrostatic action to reduce an interval between the first electrode layer 610 and the second electrode layer 620. For example, the first electrode layer 610 is bent toward the second electrode layer 620 by an electrostatic action, thereby blocking the first gas channel 710, and gas cannot pass through the first gas channel 710.

For example, as shown in FIGS. 11 and 12, the second electrode layer 620 is bonded to the second substrate 520 by the adhesive layer 871, the first electrode layer 610 is disposed on a side of the functional layer 830 away from the second electrode layer 620, and when the first electrode layer 610 is electrostatically bent toward the second electrode layer 620, the functional layer 830 is bent toward the second electrode layer 620 along with the first electrode layer 610 to the functional layer 830 is in contact with the second electrode layer 620 to block the first gas channel 710.

In some examples, as shown in FIGS. 11 and 12, the second electrode layer 620 is disposed on a surface of the second substrate 520 facing the first electrode layer 610, a plurality of second spacers 870 are disposed between the first electrode layer 610 and the second substrate 520, a chamber 872 is formed between adjacent second spacers 870, the pump portion includes at least three chambers 872, the valve portion includes at least one chamber 872, and the second electrode layer 620 is located in the chambers 872. For example, the functional layer 830, the second spacer 870, and the second substrate 520 form a chamber 872, which is a chamber that includes the first gas channel 710.

For example, as shown in FIGS. 11 and 12, the functional layer 830 is bonded to the second spacer 870 by an adhesive layer 871.

In some embodiments, as shown in FIGS. 11 and 12, the second spacer 870 has a thickness of 3-15 microns. For example, the second spacer 870 has the thickness of 4-12 microns. For example, the second spacer 870 has the thickness of 5-10 microns. For example, the second spacer 870 has the thickness of 6-14 microns. For example, the second spacer 870 has the thickness of 7-9 microns. For example, the second spacer 870 has the thickness of 8-13 microns. The greater the thickness of the second spacer, the greater the depth of the chamber, and the greater the amplitude of the bending movement of the first electrode layer and the functional layer, the more gas flow can be output.

For example, as shown in FIGS. 1-12, in the micro electro mechanical system device according to the present disclosure, the functional layer 830 may have an amplitude of up to about 4 microns at a driving voltage of 30-90 V and a driving frequency of 1-20 kHz to achieve better device performance.

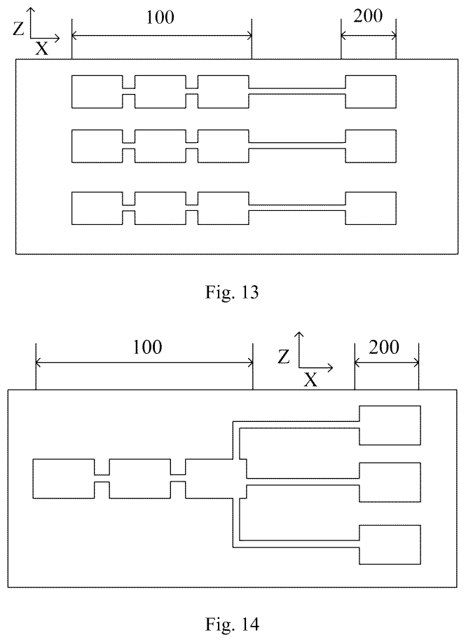

FIGS. 13 and 14 are schematic diagrams of partial planar structures of micro electro mechanical system devices provided according to different examples of an embodiment of the present disclosure.

In some examples, as shown in FIGS. 13 and 14, in the micro electro mechanical system device, the number of pump portions 100 is at least one, the number of valve portions 200 is at least one, and at least one pump portion 100 is in communication with at least one valve portion 200.

For example, as shown in FIGS. 13 and 14, different valve portions 200 may be correspondingly provided with the scent materials having different odors.

For example, as shown in FIG. 13, the number of the pump portions 100 is plural, the number of the valve portions 200 is plural, the number of the pump portions 100 is the same as the number of the valve portions 200, and the plurality of pump portions 100 communicate with the plurality of valve portions 200 in one-to-one correspondence.

For example, as shown in FIG. 13, the pump portions 100 communicating with each other may be switched on and off synchronously.

For example, as shown in FIG. 14, the number of pump portions 100 is smaller than the number of valve portions 200, and one pump portion 100 may communicate with a plurality of valve portions 200.

For example, as shown in FIG. 14, the time during which the pump portion 100 is in the open state may be greater than the time during which either of the valve portions 200 is in the open state, and the release of different scents may be achieved by opening different valve portions 200 in different periods.

The micro electro mechanical system device provided by the embodiments of the present disclosure can integrate at least one pump portion with a plurality of valve portions to achieve conversion of different smells to improve user usage experience.

The following statements should be noted:
(1) The accompanying drawings involve only the structure(s) in connection with the embodiment(s) of the present disclosure, and other structure(s) can be referred to common design(s).
(2) In case of no conflict, features in one embodiment or in different embodiments can be combined.

What have been described above are only specific implementations of the present disclosure, the protection scope of the present disclosure is not limited thereto. The protection scope of the present disclosure should be based on the protection scope of the claims.

1. A micro electro mechanical system device, comprising:
a pump portion, a valve portion, an air inlet, and an air outlet, an interval channel being provided between the pump portion and the valve portion, a gas being configured to sequentially pass through the air inlet, the pump portion, the interval channel, the valve portion, and the air outlet,
wherein at least one of a side of the valve portion away from the air outlet and an inside of the valve portion is provided with an accommodating region, the gas is configured to be discharged from the air outlet after passing through the accommodating region;
the micro electro mechanical system device comprises a first substrate, a first electrode layer, a second electrode layer, and a second substrate which are sequentially stacked, an interval is arranged between the first electrode layer and the second electrode layer, after the first electrode layer and the second electrode layer are configured to generate a voltage difference, a distance between the second electrode layer and the first electrode layer is reduced to provide a first gas channel configured to circulate the gas, or to block the first gas channel;
the pump portion and the valve portion share the first substrate and the second substrate, the pump portion comprises a first electrode and a second electrode which are oppositely disposed, the valve portion comprises a third electrode and a fourth electrode which are oppositely disposed, the first electrode layer comprises the first electrode and the third electrode, the second electrode layer comprises the second electrode and the fourth electrode, the first electrode and the third electrode are insulated from each other, and/or, the second electrode and the fourth electrode are insulated from each other.

2. The micro electro mechanical system device of claim 1, wherein the first electrode layer and the second electrode layer are configured such that after a voltage difference is generated, the second electrode layer bends toward the first electrode layer to provide the first gas channel between the second electrode layer and the second substrate.

3. The micro electro mechanical system device of claim 1, further comprising:
a third substrate located at a side of the second substrate away from the first substrate,
wherein the pump portion and the valve portion share the third substrate, and an interval is provided between the second substrate and the third substrate as a second gas channel for circulating the gas, the second gas channel comprises the interval channel;
the second substrate is provided with a first channel and a second channel penetrating through the second substrate in a direction perpendicular to the second substrate, the pump portion comprises the first channel, the valve portion comprises the second channel, the air inlet is communicated with the first channel of the pump portion, the first gas channel and the second gas channel, and the air outlet is communicated with the second channel of the valve portion, the first gas channel and the second gas channel.

4. The micro electro mechanical system device of claim 3, wherein the accommodating region comprises a first groove disposed on a side of the third substrate facing the second substrate, the first groove is configured to place a scent material.

5. The micro electro mechanical system device of claim 3, further comprising:
a barrier located between the second electrode layer and the second substrate and configured to block the first gas channel when a voltage difference is not generated between the first electrode layer and the second electrode layer,
wherein, in the direction perpendicular to the second substrate, the barrier has no overlap with both the first channel and the second channel.

6. The micro electro mechanical system device of claim 5, wherein at least one of the pump portion and the valve portion is provided with the barrier.

7. The micro electro mechanical system device of claim 2, further comprising:
a third electrode layer between the second electrode layer and the second substrate,
wherein the third electrode layer is provided with a space from the second electrode layer, and the third electrode layer is configured such that upon generating a voltage difference with the second electrode layer, the second electrode layer bends toward the third electrode layer to block the first gas channel.

8. The micro electro mechanical system device of claim 7, wherein at least one of the pump portion and the valve portion is provided with the third electrode layer.

9. The micro electro mechanical system device of claim 3, wherein the third substrate is provided with the air inlet and the air outlet penetrating the third substrate in a direction perpendicular to the third substrate, the air inlet communicates with the first gas channel through the first channel, and the air outlet communicates with the first gas channel through the second channel.

10. The micro electro mechanical system device of claim 3, wherein a plurality of spacing parts is disposed between the second substrate and the third substrate, the second gas channel is formed between adjacent spacing parts, and the spacing parts do not overlap with both the first channel and the second channel in the direction perpendicular to the second substrate.

11. The micro electro mechanical system device of claim 10, wherein the spacer part comprises an adhesive layer to bond the second substrate and the third substrate.

12. The micro electro mechanical system device of claim 1, further comprising:
a functional layer between the first substrate and the second substrate;
a first adhesive layer between the functional layer and the first substrate to bond the functional layer and the first substrate;
a second adhesive layer between the functional layer and the second substrate to bond the functional layer and the second substrate,
wherein the second electrode layer is disposed on the functional layer.

13. The micro electro mechanical system device of claim 1, wherein a side of the first substrate facing the second substrate is provided with a plurality of second grooves, at least portions of the first electrode layer are located in the plurality of second grooves, the pump portion comprises at least three second grooves arranged in a first direction to form at least three pump chambers, the valve portion comprises at least one second groove to form at least one valve chamber, and an orthographic projection of the second electrode layer on the first substrate is completely located in the plurality of second grooves.

14. The micro electro mechanical system device of claim 13, wherein the first electrode layer and the second electrode layer corresponding to adjacent pump chambers are configured such that at least in part of time periods for applying electricity are staggered.

15. The micro electro mechanical system device of claim 1, wherein a side of the first electrode layer facing the second substrate is provided with a plurality of first spacers, a chamber is formed between adjacent first spacers, the pump portion comprises at least three chambers, the valve portion comprises at least one chamber, and an orthographic projection of the second electrode layer on the first substrate is completely located in an orthographic projection of the chamber on the first substrate.

16. The micro electro mechanical system device of claim 1, wherein after the first electrode layer and the second electrode layer are configured to generate a voltage difference, the first electrode layer bends toward the second electrode layer to block the first gas channel between the first electrode layer and the second electrode layer.

17. The micro electro mechanical system device of claim 16, wherein the second electrode layer is disposed on the second substrate, the second electrode layer is disposed between the second substrate and the first electrode layer, a plurality of second spacers are disposed between the first electrode layer and the second substrate, a chamber is formed between adjacent second spacers, the pump portion comprises at least three chambers, the valve portion comprises at least one chamber, and the second electrode layer is located in the chamber.

18. The micro electro mechanical system device of claim 1, wherein the pump portion comprises at least one pump portion, the valve portion comprises at least one valve portion, and the at least one pump portion is in communication with the at least one valve portion.

19. The micro electro mechanical system device of claim 13, wherein a depth of the second groove is 3-15 microns, a dimension of the second groove in a second direction is 1-5 millimeters, a dimension of the second groove in the first direction is 1-5 millimeters, a distance between adjacent second grooves in the pump portion is 1-3 mm, and the second direction is perpendicular to the first direction and parallel to the second substrate.

20. (canceled)

21. The micro electro mechanical system device of claim 15, wherein the first spacer has a thickness of 2-10 microns.

22. (canceled)
